(19) United States
(12) Patent Application Publication
(10) Pub. No.: US 2008/0030690 A1
(43) Pub. Date: Feb. 7, 2008

(54) Projection Device with a Blower and a Nozzle disposed on a Bracket

(76) Inventor: Yi-Ting Hsu, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/779,889

(22) Filed: Jul. 19, 2007

(30) Foreign Application Priority Data
Aug. 7, 2006 (TW) 095128823

(51) Int. Cl. G03B 21/16; H05K 7/20

(52) U.S. Cl. 353/61; 165/121

(57) ABSTRACT

A projection device with a blower and a nozzle disposed on a bracket is provided. The projection device includes a light-emitting device and a cooling module for cooling it. The cooling module includes a bracket, a blower disposed on the bracket for generating a wind, and a nozzle detachably disposed on the bracket. The nozzle includes an input overlapped with an output of the blower, and an output next to the light-emitting device. The output of the nozzle is for guiding the wind generated by the blower to cool the light-emitting device.

### BACKGROUND OF THE INVENTION

1. Field of the Invention

The present invention relates to a projection device, and more particularly, to a projection device with a blower and a nozzle disposed on a bracket.

2. Description of the Prior Art

Among most projection devices, images are generated with light, which is generated with a bulb, passing through a light machine. The best efficiency and life cycle of said bulb may be achieved with a stable essential temperature and cooling. Therefore, the essential temperature of the bulb has to be manipulated with delicate mechanical elements. In a conventional projection device, a blower is disposed near a bulb for generating a wind to cool said bulb. For aiming the generated wind at the bulb, a nozzle is disposed at an output of the blower for guiding said wind towards said bulb precisely, and for cooling said bulb efficiently. The direction the nozzle positioned towards is dominant for controlling the temperature of the projection device.

The outlet of the blower and the inlet of the nozzle are necessarily overlapped for preventing the wind from leaking. In conventional fabrication, the nozzle and the blower are fixed with each other by screws or glue. However, the former increases costs, and the later cannot avoid a likely detachment between the nozzle and the blower. For example, glue is easily spoiled with long-term ultraviolet-rays emitted from a light-emitting device, therefore, a nozzle and a blower, both of which are fixed to each other with glue originally, are likely to be separated with the spoiled glue. Moreover, it is complicated to disassemble the combination of the nozzle and blower when replacing or recycling elements is necessary.

### SUMMARY OF THE INVENTION

The claimed invention provides a projection device with a blower and a nozzle disposed on a bracket. The projection device comprises a light-emitting device and a cooling module. The cooling module comprises a bracket, a blower, and a nozzle detachably disposed on the bracket. The blower has a first output, and is disposed on the bracket for generating a wind. The nozzle comprises an input overlapped with the first output of the blower, and a second output located next to the light-emitting device for guiding the wind out of said nozzle.

The claimed invention also provides a cooling module having a blower and a nozzle both disposed on a bracket. The cooling module comprises a bracket, a blower, and a nozzle detachably disposed on the bracket. The blower has a first output and is disposed on the bracket for generating a wind. The nozzle comprises an input overlapped with the first output of the blower, and a second output for guiding the wind out of the nozzle.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a projection device with a blower and a nozzle disposed on a bracket of the present invention.

FIG. 2 illustrates an exploded diagram of a cooling module of the projection device shown in FIG. 1 according to a first embodiment of the present invention.

FIG. 3 illustrates an exploded diagram of a cooling module of the projection device shown in FIG. 1 according to a second embodiment of the present invention.

FIG. 4 illustrates an exploded diagram of a cooling module of the projection device shown in FIG. 1 according to a third embodiment of the present invention.

### DETAILED DESCRIPTION

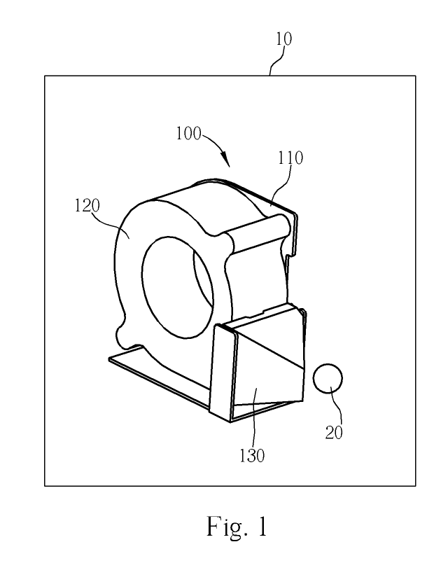

Please refer to FIG. 1, which illustrates a projection device 10 with a blower and a nozzle disposed on a bracket of the present invention. The projection device 10 of the present invention comprises a light-emitting device 20, a cooling module 100, and other necessary parts of a conventional projection device where said parts are not illustrated in FIG. 1. The cooling module 100 is for cooling the light-emitting device 20. The cooling module 100 comprises a bracket 110, a blower 120, and a nozzle 130. The blower 120 is disposed on the bracket 110 for generating a wind. The nozzle 130 is disposed on the bracket 110 in a detachable manner. An input of the nozzle 130, which is not illustrated in FIG. 1, is located next to an output of the blower 120, which is not illustrated in FIG. 1 either. The output of the nozzle 130 is guided towards the light-emitting device 20.

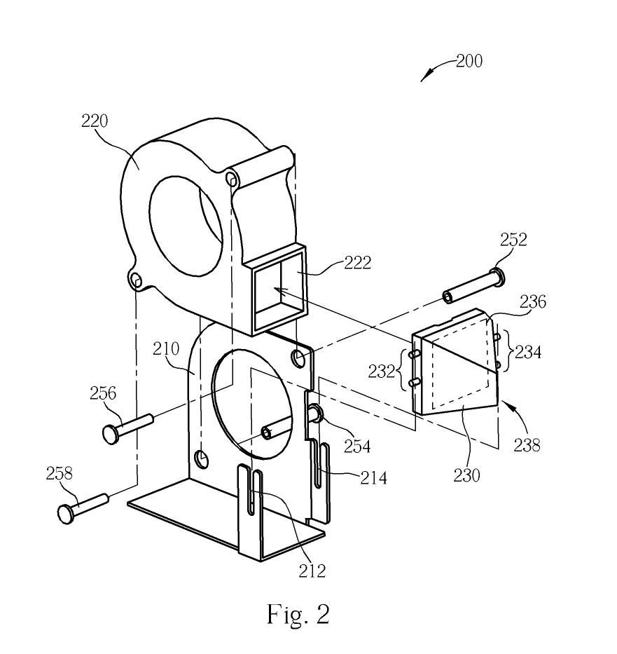

Please refer to FIG. 2, which illustrates an exploded diagram of a cooling module 200 of the projection device shown in FIG. 1 according to a first embodiment of the present invention. The cooling module 200 comprises a bracket 210, a blower 220, and a nozzle 230. The bracket 210 may be implemented in a monolithic manner. The blower 220 is disposed on the bracket 210, and comprises a first output 222 for generating the wind. The nozzle 230 is disposed on the bracket 210 is a detachable manner. The nozzle 230 is hollow, and comprises an input 236 and a second output 238. The input 236 covers the first output 222 of the blower 220. The second output 238 guides the wind out the nozzle 230 to cool the light-emitting device 20 in FIG. 1. In the first embodiment of the present invention, the second output 238 of the nozzle 230 is not parallel with the input 236 of the nozzle 230 to change the wind's direction. In the cooling module 200, the blower 220 is fixed on the bracket 210 with a plurality of fixers 252, 254, 256, and 258. The fixers 252 and 256 are in a pair whereas the fixers 254 and 258 are in a pair also. The plurality of fixers 252, 254, 256, and 258 may be rivets, screws, or any engaging elements having clasps at both terminals, where a clasp at one terminal of said engaging element may be engaged with the blower 220 whereas another clasp at the other terminal of said engaging element is engaged with the bracket 210. A first engaging component 212 is disposed on the bracket 210, and a second engaging component 232 is disposed on the nozzle 230 corresponding to the first engaging component 212. The second engaging component 232 is engaged with the first engaging component 212 in a detachable manner, where the first engaging component 212 and the second engaging component 232 are in a pair. In the first embodiment of the present invention, the first engaging component 212 is a primary female component such as a groove whereas the second engaging component 232 is a primary male component such as a raised shaft. Note that the first engaging component 212 may also be a primary male component whereas the second engaging component 232 is a primary female component. A third engaging component 214 may further be disposed on the bracket 210. A fourth engaging component 234 may also be disposed on the nozzle 230 corresponding to the third engaging component 214. The fourth engaging component 234 is engaged with the third engaging component 214 in a detachable manner. Moreover, the third engaging component 214 and the fourth engaging component 234 are in a pair. In a preferred embodiment of the present invention, the third engaging component 214 may be an auxiliary male component such as a raised shaft whereas the fourth engaging component 234 is an auxiliary female component such as a groove. Note that the third engaging component 214 may also be an auxiliary female component whereas the fourth engaging component 234 is an auxiliary male component. In a preferred embodiment of the present invention, the first engaging component 212 differs from the third engaging component 214 in size whereas the second engaging component 232 also differs from the fourth engaging component 234 in size. For example, the size of the first engaging component 212 may be larger than the size of the third engaging component 214 whereas the size of the second engaging component 232 is also larger than the size of the fourth engaging component 234. Therefore, a fool-proof design between the nozzle 230 and the bracket 210 is formed by the abovementioned engaging components differing in size, which prevents assembling the nozzle 230 towards a wrong direction.

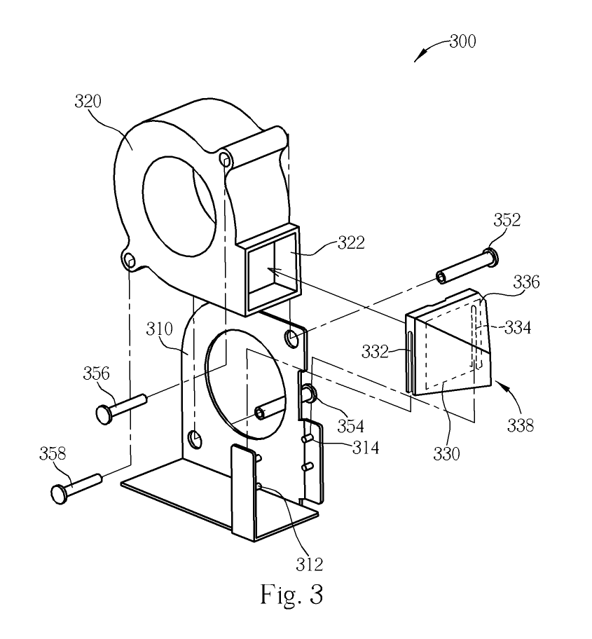

Please refer to FIG. 3, which illustrates an exploded diagram of a cooling module 300 of the projection device shown in FIG. 1 according to a second embodiment of the present invention. An implementation of the cooling module 200 is similar with the cooling module 300 shown in FIG. 3 in most elements, where most elements shown in FIG. 3 are assigned with serial numbers corresponding to the serial numbers denoted in FIG. 2. A primary difference between the cooling modules 200 and 300 lies in the connection between a first engaging component 312 and a second engaging component 332 and that between a third engaging component 314 and a fourth engaging component 334. As shown in FIG. 3, the first engaging component 312 is a primary male component, and the second engaging component 332 is a primary female component. The third engaging component 314 is an auxiliary male component, and the fourth engaging component 334 is an auxiliary female component 334.

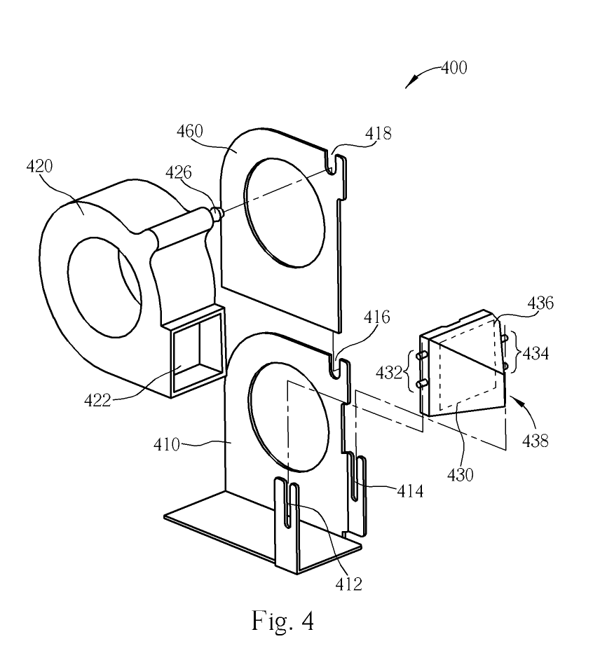

Please refer to FIG. 4, which illustrates an exploded diagram of a cooling module 400 of the projection device shown in FIG. 1 according to a third embodiment of the present invention. An implementation of the cooling module 200 is similar with the cooling module 400 shown in FIG. 4 in most elements, where most elements shown in FIG. 4 are assigned with serial numbers corresponding to the serial numbers denoted in FIG. 2. Differences between the cooling modules 400 and 200 lie in the combination of the bracket 410 and the blower 420, and in that the cooling module 400 further comprises an elastic pad 460. The bracket 410 includes a groove 418 to locate a raised shaft 426 of the blower 420. Thus, the bracket 410 positions the blower 420 without additional components. Moreover, a vibration of the blower 420 is caused when the blower 420 rotates to generate the wind. The elastic pad 460 disposed between the bracket 410 and the blower 420 absorbs the vibration and stabilizes the cooling modules 400. A groove 418 on the elastic pad 460 also indicates a fool-proof design for preventing errors during the fabrication of the bracket 410 and the blower 420.

In the present invention, a projection device with a blower and a nozzle disposed on a bracket is provided. A blower and a nozzle are combined by a bracket without screws or glue, and also easily disassembled if replacing or recycling components is necessary. Especially the nozzle can be precisely positioned towards the correction direction by matching engaging components which differ in size (the so-called fool-proof design). Moreover, an elastic pad is further disposed between the nozzle and the bracket for maintaining the cooling module stable when it operates.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A projection device with a blower and a nozzle disposed on a bracket comprising:
a light-emitting device; and
a cooling module comprising:
a bracket;
a blower, which has a first output, disposed on the bracket for generating a wind; and
a nozzle detachably disposed on the bracket, the nozzle comprising:
an input overlapped with the first output of the blower; and
a second output located next to the light-emitting device for guiding the wind to cool the light-emitting device.

2. The projection device of claim 1 wherein the cooling module further comprises:
at least one fixer connected to the blower and to the bracket for fixing the blower on the bracket.

3. The projection device of claim 1 wherein the cooling module further comprises:
a first engaging component disposed on the bracket; and
a second engaging component disposed on the nozzle and detachably engaged with the first engaging component.

4. The projection device of claim 3 wherein the first engaging component is a primary female component, and the second engaging component is a primary male component.

5. The projection device of claim 3 wherein the first engaging component is a primary male component, and the second engaging component is a primary female component.

6. The projection device of claim 3 wherein the cooling module further comprises:
a third engaging component disposed on the bracket opposite to the first engaging component; and
a fourth engaging component disposed on the nozzle and detachably engaged with the third engaging component.

7. The projection device of claim 6 wherein the third engaging component is an auxiliary female component, and the fourth engaging component is an auxiliary male component.

8. The projection device of claim 6 wherein the third engaging component is an auxiliary male component, and the fourth engaging component is an auxiliary female component.

9. The projection device of claim 1 wherein the cooling module further comprises:
an elastic pad disposed between the bracket and the blower.

10. A cooling module having a blower and a nozzle both disposed on a bracket comprising:
a bracket;
a blower, which has a first output, disposed on the bracket for generating a wind; and
a nozzle detachably disposed on the bracket comprising:
an input overlapped with the first output of the blower; and
a second output for guiding the wind out of the nozzle.

11. The cooling module of claim 10 further comprising:
at least one fixer connected to the blower and to the bracket for fixing the blower on the bracket.

12. The cooling module of claim 10 further comprising:
a first engaging component disposed on the bracket; and
a second engaging component disposed on the nozzle and detachably engaged with the first engaging component.

13. The cooling module of claim 12 wherein the first engaging component is a primary female component, and the second engaging component is a primary male component.

14. The cooling module of claim 12 wherein the first engaging component is a primary male component, and the second engaging component is a primary female component.

15. The cooling module of claim 12 further comprising:
a third engaging component disposed on the bracket opposite to the first engaging component; and
a fourth engaging component disposed on the nozzle and detachably engaged with the third engaging component.

16. The cooling module of claim 15 wherein the third engaging component is an auxiliary female component, and the fourth engaging component is an auxiliary male component.

17. The cooling module of claim 15 wherein the third engaging component is an auxiliary male component, and the fourth engaging component is an auxiliary female component.

18. The cooling module of claim 10 wherein the cooling module further comprising an elastic pad disposed between the bracket and the blower.
